(19) United States
(12) Patent Application Publication
(10) Pub. No.: US 2017/0013724 A1
(43) Pub. Date: Jan. 12, 2017

(54) TRACKS PATTERNS PRODUCTION APPARATUS

(71) Applicant: UTILIGHT LTD, Yavne (IL)

(72) Inventor: Amir Noy, Kfar Mordechai (IL)

(21) Appl. No.: 15/121,035

(22) PCT Filed: Feb. 5, 2015
(86) PCT No.: PCT/IL15/00006

§ 371 Date: Aug. 24, 2016

Related U.S. Application Data
(60) Provisional application No. 61/945,834, filed on Feb. 28, 2014.

(51) Int. Cl. H05K 3/10; H05K 13/00; H05K 3/12; H05K 3/26

(52) U.S. Cl. CPC H05K 3/107; H05K 3/26; H05K 13/0061; H05K 3/1258; H05K 2203/0139; H05K 2203/082

(57) ABSTRACT

Presented is an apparatus for generating a transfer pattern to be used in a transfer printing process. The pattern is generated in a substrate that could be a web substrate and that bears one or more trenches. A filler to be transferred is made to fill the trenches within the web substrate. Upon completion of the trench by filler filling, the substrate, the scraper and the squeegee are translated from the working zone in a synchronized movement, such that in course of the translation movement at least the scraper remains in full contact with the substrate.

### TECHNOLOGY FIELD

The present apparatus is directed to low cost, mass production of tracks patterns on continuous flexible substrate.

### BACKGROUND

Recently there has been a growing interest in reliable and economical processes for the printed electronics fabrication. Of special interest are fabrication processes supporting production of conductive or non-conductive patterns on polymer flexible substrates, and particularly in roll-to-roll manufacturing process. These fabrication methods allow for direct patterning of various microscale metallic structures finding use in contemporary electronics, decorative art and other industries. The technical challenges are numerous including control of feature size (both width and thickness), production of small and reproducible features, and integration with other traditional electronics processing techniques.

Different printing processes including fine mesh screen printing, inkjet printing, and offset printing have been tested and continue to be tested to reach finer conductor width. Screen printing is a printing process in course of which a paste or ink is pressed onto portions of an underlying structure (screen frame) through openings in the emulsion on a screen. The resolution of the process depends on the openings in the screen and the nature of the paste. With a 325-mesh screen (i.e., 325 wires per inch or 40 micron square holes) and a typical paste, a lateral resolution of 100 micron can be obtained. The aspect ratio of the finer screens still limits the height of the printed conductors and a further increase in screen mesh count adversely affects the integrity of a screen printed conductor and its resistance.

Potential applications of printed electronics include mobile phones antennas, decorative and functional automotive glasses and other applications. The width of conductors that could be achieved supports further devices miniaturization and increases packaging density.

### GLOSSARY

As used herein, the term “trench” refers to an indentation or a recess formed in a substrate. A trench could be made by embossing, engraving, etching and other methods. A trench can be of any shape or size as long as it separates two adjacent elements creating shoulders one on either side of the trench. Typically, a trench has a width smaller than length.

As used herein, the term “squeegee” refers to a tool that has a soft blade with typical hardness of 65-90 durometer and that is used for spreading or wiping paste or liquid on, across, or off a surface. In screen printing a squeegee passes over the screen frame mesh and squeezes the ink or paste through the open areas of the mesh depositing it onto the substrate surface. Squeegee could be made of Rubber, Neoprene, and Polyurethane.

As used herein, the term “scraper” refers to a tool or device used for scraping, especially for removing dirt, paint, paste or other unwanted matter from a surface. In some instances a scraper could have a relatively soft blade, but much harder than a squeegee blade, typically exceeding 95 durometer. The scraper blade could be made even from metal or hard plastic material.

### SUMMARY

Presented is an apparatus for generating a transfer pattern to be used later in a transfer printing process. The pattern is generated in a substrate that could be a web substrate and that bears one or more trenches. A filler to be transferred is made to fill the trenches within the web substrate. The apparatus includes a support configured to receive a segment of the web substrate with one or more trenches and a squeegee configured to fill the trench with a filler deposited on the web substrate by a filler delivery mechanism. Upon completion of the trench by filler filling, the substrate and the squeegee are translated from the working zone in a synchronized movement, such that in course of the translation movement the squeegee remains in full contact with the substrate.

In one example, a scraper configured to follow the squeegee and remove from the web substrate excess filler occasionally deposited on area surrounding the trench. Upon completion of the trench filling the substrate, the squeegee, and the scraper are retracted (translated) in a synchronized movement. In course of the retraction at least the scraper remains in full contact with the substrate. In one example, the substrate, the squeegee, and the scraper are retracted (translated) in a synchronized movement. In course of the retraction the scraper and the squeegee remain in full contact with the substrate.

The apparatus also includes a mechanism that supports collection by the scrapper and recycling of the excess filler from the substrate. Scraper accumulates the excess filler removed from the substrate on the substrate in front the scraper and on the surface of the scraper facing the squeegee.

In order to collect the excess filler from the surface of the scraper, the squeegee elevates, translates towards the scraper, contacts the scraper surface with the excess filler and descends towards the substrate while collecting the excess filler accumulated along the surface of the scraper. The squeegee transfers and combines (recycles) the excess filler collected from the surface of the scraper with the filler deposited on the substrate by a filler delivery mechanism.

The apparatus also includes different auxiliary units or devices such web substrate movement device, a vacuum device supporting substrate hold down, and other devices as it could be required by the apparatus operation.

### BRIEF LIST OF DRAWINGS AND THEIR DESCRIPTION

FIG. 1 is a block schema of an example of an apparatus for generating a transfer printing mask supporting transfer of conductor lines with width of about 20-25 micron;

FIG. 2 is schematic illustration of an example of a trenches filling unit or device of an apparatus for generating a transfer printing mask supporting transfer of conductor lines with width of about 20-25 micron;

FIG. 3 is a schematic illustration of squeegee and substrate retraction according to an example;

FIG. 4 is a schematic illustration of an example of a repeat processes of filler into a pattern of trenches filling;

FIG. 5A is top view of segment of a substrate that illustrates occasional residual filler spot on sides of trenches filled-in by a filler;

FIGS. 5B-5C are schematic illustrations of additional examples of trench patterns;

FIG. 6 is schematic illustration of another example of a unit or device of an apparatus for producing conductor lines with width of about 20-25 micron;

FIG. 7 illustrates an example of squeegee, scraper and substrate relative location at the end of trenches filling procedure;

FIG. 8 is a schematic illustration of squeegee, scraper, and substrate retraction according to an example;

FIGS. 9A-9D are schematic illustrations of an example of excessive filler collected by scraper removal from the scraper and recycling of the removed filler into a main filler mass;

FIG. 10 is a schematic illustration of an example of a repeat processes of filler into a pattern of trenches filling; and

FIG. 11 is a schematic illustration of an example of a transfer device configured to transfer a pattern of trenches filled by filler onto a receptor object.

### BRIEF DESCRIPTION

Different printing processes described above do not support printing or generation of conductor or finger lines narrower than 75-100 micron. Contemporary electronics technology could also benefit of narrower than currently possible to produce conductor lines. For example RFID tags, bar codes could be produced at the same settings as the rest of the electronics is produced.

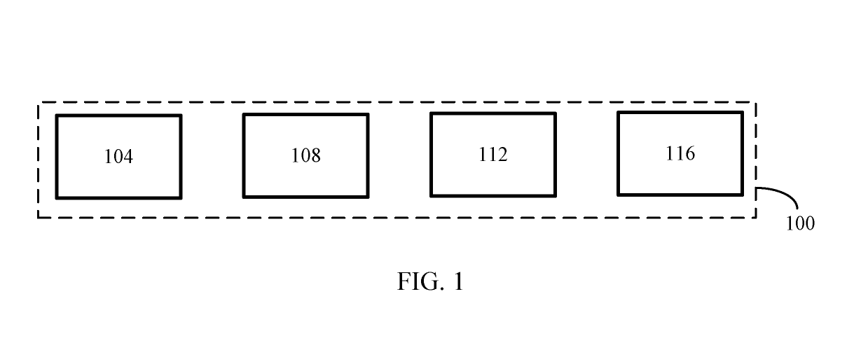

FIG. 1 is a block schema of an example of an apparatus for generating conductor lines with width of about 20-25 micron. Apparatus 100 includes a unit or device 104 configured to deliver a substrate that could be in form of a continuous web or sheet cut and bears a pattern of trenches to different units or devices of apparatus 100; a unit or device 108 configured to fill-in the trenches by a conductive paste; a transfer unit or device 112 where the conductive paste that fills-in the trenches is transferred to a receptor and a collection unit or device 116 that collects and removes the used substrate. In some examples, collection unit 116 could collect for further use and delivery to a different location substrate with filled-in trenches. The receptor could be a silicon substrate or wafer, a ceramic support of an electronic circuit, a decorative glass or other substrate.

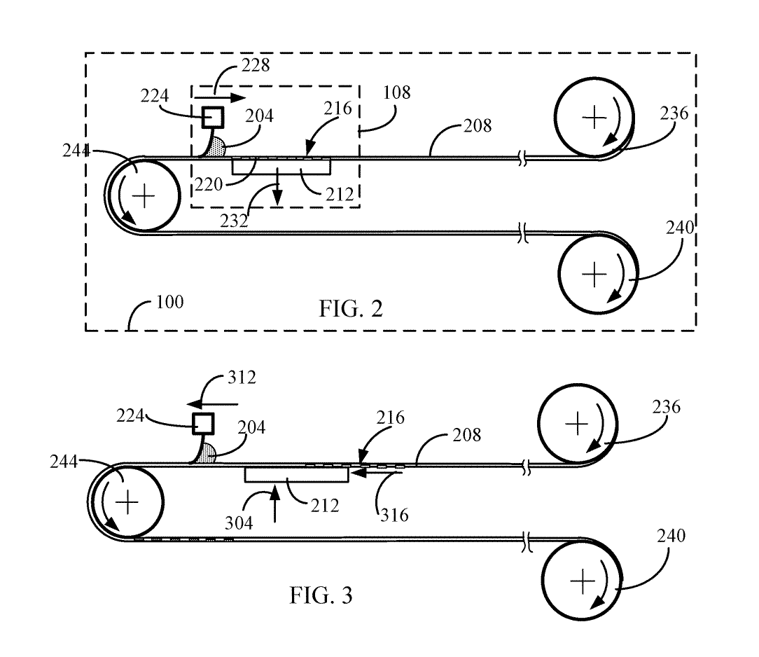

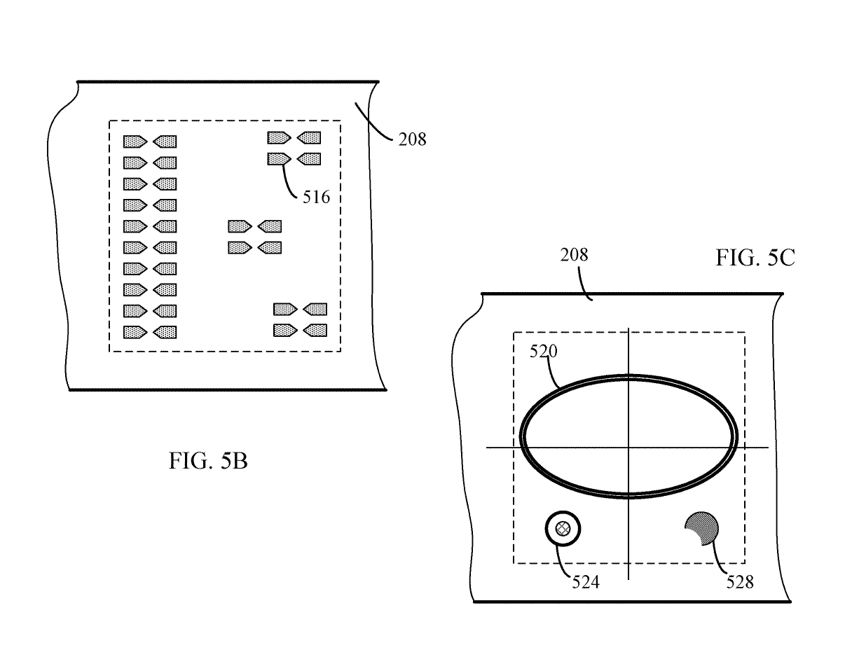

FIG. 2 is schematic illustration of an example of a unit or device 108 of an apparatus for producing transfer masks for conductor lines with width of about 20-25 micron. Device 108 includes a filler delivery mechanism (not shown). The filler could be a conductive paste or an organic polymer delivered by a delivery device configured to deposit a filler 204 on web substrate 208, a support 212 configured to receive and hold a segment 216 of the web substrate 208 with at least one trench 220 or a pattern of trenches into a working zone of device 108, a squeegee 224 configured to fill-in the trench with a filler 204 deposited on the substrate by a filler delivery mechanism. The trenches, illustrated in detail in FIG. 5 could be 10 to 40 micron deep and 10 to 60 micron wide and typically would be 20-25 micron wide. For filling the trench or a pattern of trenches, squeegee 224 moves in the direction indicated by arrow 228. Support 212 is connected to a source of negative pressure, which could be a vacuum pump (not shown). Concurrently with squeegee 224 movement in the direction of arrow 228 the source of negative pressure becomes operative and applies vacuum as schematically shown by arrow 232 to support 212. The source of negative pressure applies vacuum through a series of orifices or channels made in the surface of support 212 facing substrate 208. The negative pressure attaches a segment 216 of substrate 208 to support 212 surface and maintains substrate segment 216 in a rigid and static form. Reference numeral 236 marks substrate 208 supply roll, reference numeral 240 marks substrate 208 collection roll and reference numeral 244 mark a part of substrate delivery device 104.

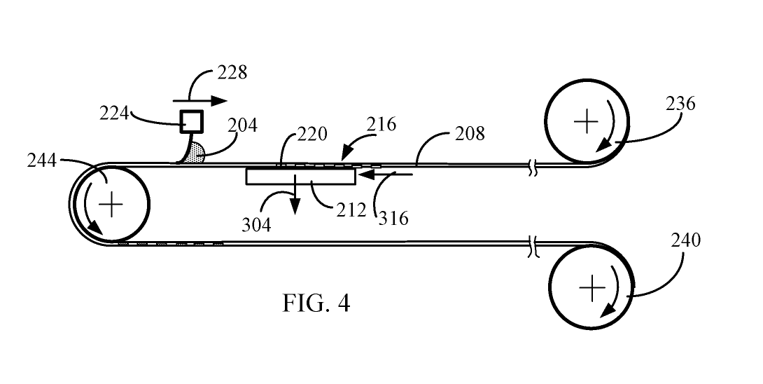

Upon completion of substrate 208 segment 216 by filler 204 filling and in particular filling of the trenches in substrate segment 216 vacuum is relived and positive pressure, as indicated by arrow 304 (FIG. 3) is supplied through the same vacuum openings or orifices of support 212 to lift off web substrate segment 216, such as to support easy web 208 movement and in particular retraction from the working zone 108. In order to prevent occasional residue or smear of filler 204 on substrate 208, upon completion of trench 216 filling web substrate 208 (FIG. 3) and squeegee 224 are retracted (translated) from the working zone of device or unit 208 in a synchronized movement as shown by arrows 312 and 316 such that in course of the retraction squeegee 224 remains in full contact with web substrate 208.

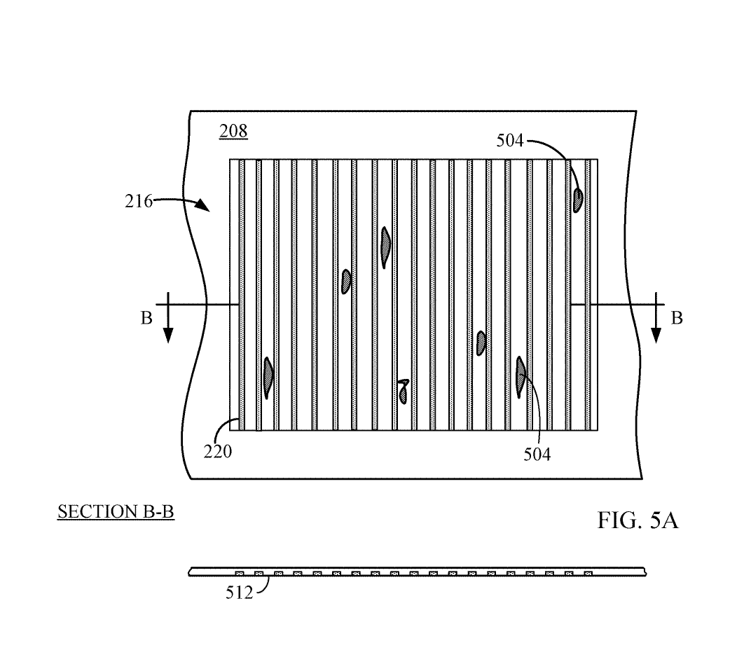

When synchronized retraction of squeegee 224 and substrate 208 being in contact with each other is completed, and a next segment 216 of web substrate 208 with at least one trench 220 or a pattern of trenches is delivered and placed over support 212 configured to receive and hold a segment 216 of the web substrate 208, supply of positive pressure is discontinued and vacuum 404 is activated once again such that filling by filer 204 of at least one trench 220 or a pattern of trenches could start (FIG. 4). The trenches filling process is similar to the one described above with relation to FIG. 2. Squeegee 224 becomes displaced and moves in the direction of arrow to spread the filler and to fill-in the trenches with filler 204 deposited on substrate 208 by a filler delivery mechanism.

In some examples, in course of the filler 204 in trenches 220 filling process, excessive filler 204 or occasional filler droplets forming spots of filler 504 on shoulders 512 of the trenches could occur. FIG. 5, which is top view of segment 216 that illustrates the occasional residual filler spots 504 on either side of the trenches 220 filled-in by conductive paste or filler 204. Trenches 220 could be 10 to 40 micron deep and 10 to 60 micron wide and typically would be 20-25 micron wide. Trenches 220 could be equidistantly spaced or the distance between them could be made variable. Synchronized retraction of squeegee 224 with substrate 208 in course of which squeegee 228 remains static with respect to substrate 20 and maintain a contact with it reduces the amount of occasionally formed residual filler spots 504. Manual residual filler spots 504 removal processes is typically applied to substrates will trenches filled-in by filler.

The pattern of trenches could be a customizable pattern. FIGS. 5B and 5C provide examples of other trench patterns that could be filled-in using the current apparatus and method. FIG. 5B is an example of a fine touch-screen conductive pattern 516 and FIG. 5C is an example of a specialized electronic product that illustrates conductors 520-528.

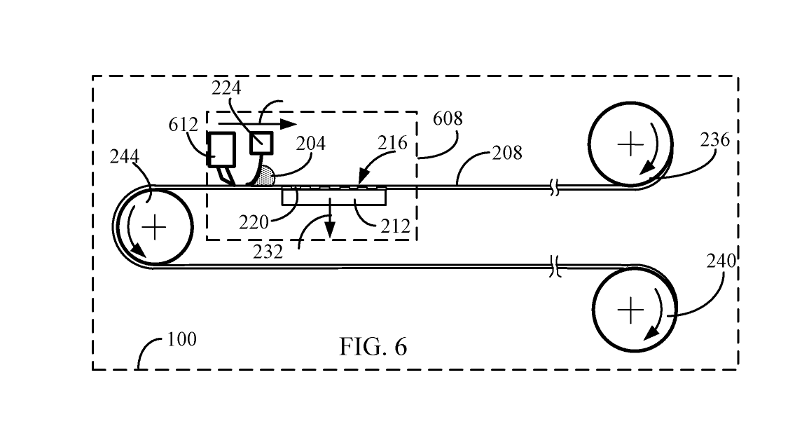

FIG. 6 is schematic illustration of another example of a device or unit of an apparatus for producing conductor lines with width of about 20-25 micron. Device 608 includes a support similar to support 212 configured to receive and translate a segment 216 of a continuous web substrate 208 with at least one trench 220 into a working zone; a squeegee 224 configured to fill the trench with a filler, wherein the filler is a conductive paste deposited on the substrate by a filler delivery mechanism (not shown) and a scraper 612 configured to follow squeegee 224 and remove from substrate 208 and in particular from area surrounding the trenches (shoulders of the trench) excess filler occasionally deposited on the trench shoulders 508.

For filling the trench or a pattern of trenches, squeegee 224 moves in the direction indicated by arrow 228. Support 212 is connected to a source of negative pressure, which could be a vacuum pump (not shown). Concurrently with squeegee 224 movement in the direction of arrow 228 the source of negative pressure becomes operative and applies vacuum as schematically shown by arrow 232 to support 212. The source of negative pressure applies vacuum through a series of orifices or channels made in the surface of support 212 facing substrate 208. The negative pressure attaches a segment 216 of substrate 208 to support 212 surface and maintains substrate segment 216 in a rigid and static form.

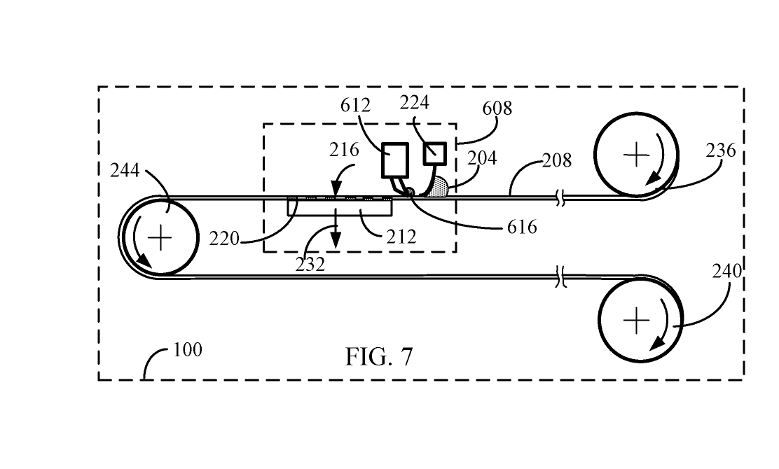

Scraper 612 that follows the squeegee removes the excess filler and residual spots 504 from the substrate and accumulates the removed from the substrate excess filler 616 (FIG. 7) on the substrate 208 in front the scraper 612 (between the squeegee and scraper) and on the surface of the scraper facing the squeegee.

FIG. 7 is an example of relative squeegee, scraper and substrate location at the end of trenches filling procedure. The squeegee and the scraper have passed the pattern of trenches. Scraper 612 has collected excessive paste 616 from the substrate and removed the excess filler from the substrate accumulating the removed from the substrate excess filler on the substrate in front the scraper (between the squeegee and scraper) and on the surface of the scraper facing the squeegee.

According to one example, upon completion of the trenches filling at least the substrate 208 and the scraper 612 are retracted (translated) from the working zone of device 608 in a synchronized movement and wherein in course of the retraction scraper 612 remains in full contact with substrate 208.

According to another example, upon completion of the trench filling the squeegee is also retracted concurrently to retracting (displacing) the scraper and the substrate (retracting the squeegee, scraper and substrate concurrently?) and maintaining in course of the retraction a constant spatial relation at least between the substrate and the scraper. The squeegee, the scraper and the substrate maintain in course of the retraction a constant spatial relation between the substrate, squeegee and the scraper.

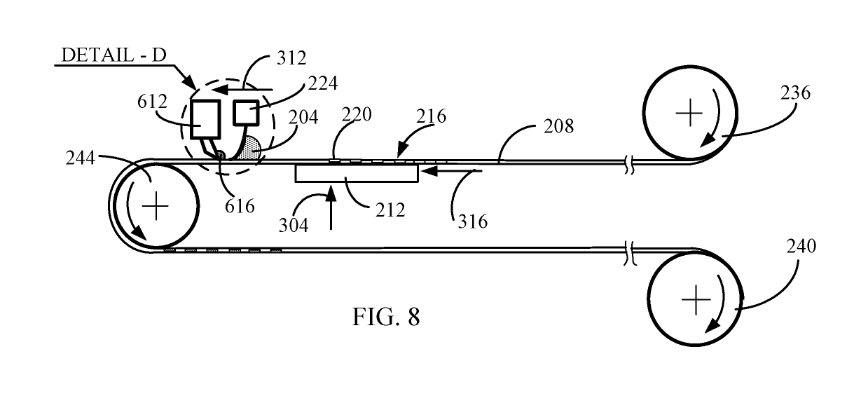

In the course of substrate 208 translation the vacuum is removed/stopped releasing the substrate 208 such as to facilitate translation of the substrate over the support and a positive pressure is built through the vacuum orifices such as to further facilitate the substrate 208 over the support 212 translation. FIG. 8 is a schematic illustration of squeegee, scraper, and support retraction according to an example.

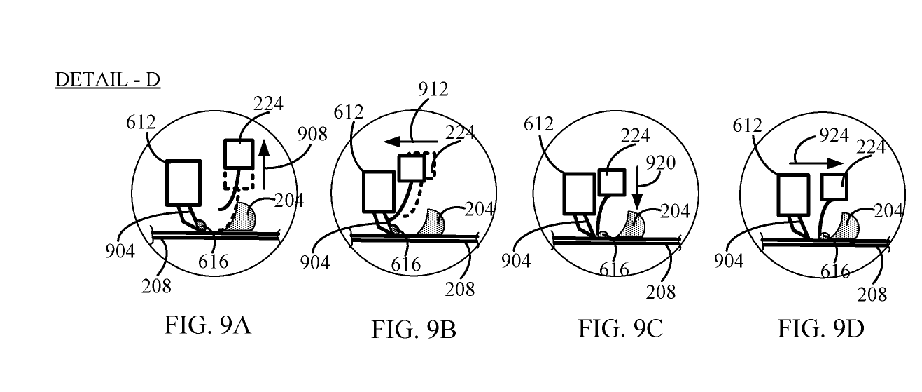

FIGS. 9A-9D is a schematic illustration of an example of excessive filler collected by scraper removal from the scraper and recycling into a main filler mass. Upon completion of the retraction, the squeegee 224 is lifted over the substrate 208 and further translated to contact a surface 904 of the scraper 612 facing the squeegee and collect the excess filler 616 accumulated on the surface 904 of the scraper facing the squeegee.

In order to collect the excess filler 616 from the surface 904 of the scraper 612 the squeegee 224 elevates as shown by arrow 908 (FIG. 9A) and is further translated as shown by arrow 912 (FIG. 9B) towards the scraper 612. Squeegee blade contacts scraper surface 904 facing the squeegee and collects the excess filler (accumulated filler). Following this squeegee 224 descends towards the substrate 208 as shown by arrow 920 (FIG. 9C) while collecting the excess filler 616 accumulated along the surface 904 of the scraper. The squeegee 224 transfers and combines (recycles) the excess filler 616 collected from the surface 904 of the scraper with the mass of filler 204 deposited on the substrate by a filler delivery mechanism. In other words the squeegee acts to recycle the excess filler 616 by transferring and combining the excess filler 616 collected from the surface 904 of the scraper 612 with the filler deposited on the substrate by a filler delivery mechanism.

The next trenches filling cycle could start following completion of filler collection and recycling.

Generally, following completion of trenches by paste filling, substrate 208 with trenches pattern filled by filler 204 could be delivered to substrate collection device 116 and in particular to roll 240 where it could be collected in a cassette or other package convenient for shipment and other uses.

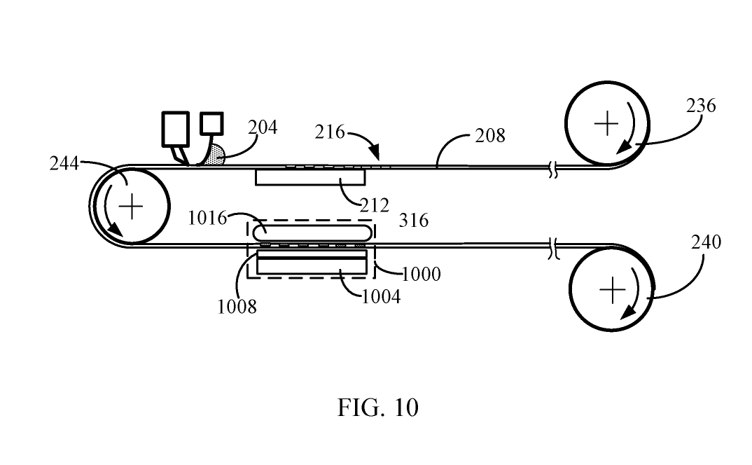

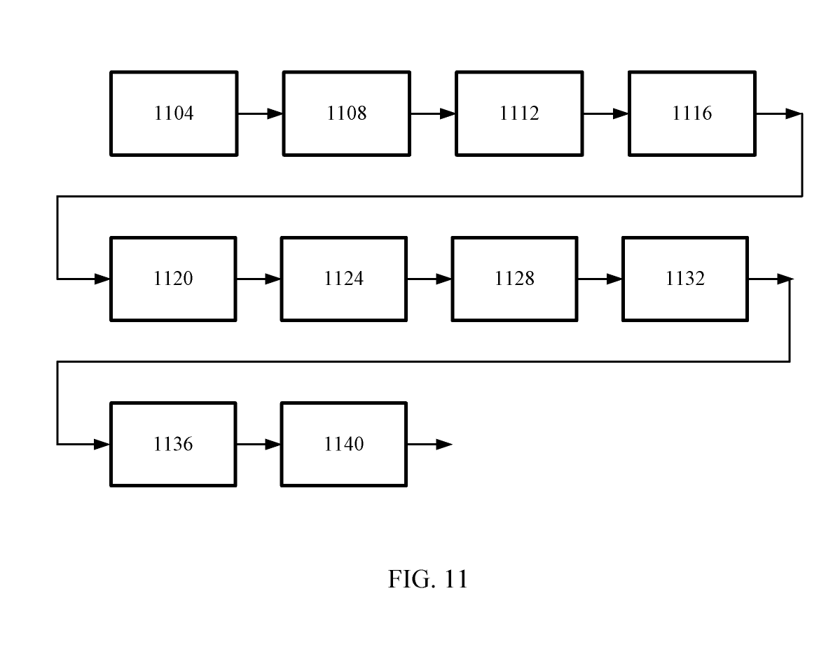

In some examples, apparatus 100 could include a transfer unit or device configured to transfer the filler from the trenches to a receptor. FIG. 10 is a schematic illustration of an example of filler from trenches to receptor transfer device of an apparatus for producing conductor lines with width of about 20-25 micron. Device 1000 includes a mechanism 1004 configured to deliver and exchange a receptor 1008 configured to receive the filler filling the trench (the transfer pattern) and a mechanism 1016 configured to transfer the filler from the trench or a pattern of trenches to the receptor 1008.

Mechanism 1016 could be a thermal transfer mechanism or other mechanism configured to transfer tracks or conductors from a pattern of 20-25 micron wide trenches. Thermal transfer could be achieved by a scanning laser beam with a scanning spot sufficiently wide to cover the width of the trench or even wider than the width of the trench. The width of the transferred conductor is equal or smaller to the width of the trench since no other conductive material or conductor exists in the vicinity of the trench. In some examples, different alignment methods and/or apparatuses could be used to align the transfer pattern with the receptor.

The present document also discloses a method for generating a transfer pattern by filling filler into a trench within a web substrate. the method includes delivering a substrate 208 (block 1104) with at least one trench into a working zone and using vacuum (block 1108) to hold substrate 208 in a rigid and static form on support 212 in course of the trenches 220 by filler 204 filling. Employing a squeegee 224 (Block 1112) to fill the trenches 220 with a filler. The filler could be deposited on substrate 208 by a filler delivery mechanism and employing a scraper 612 (Block 1116) configured to follow squeegee 224 and remove from substrate 208 the excess filler 504 occasionally deposited on areas 512 surrounding the trenches 220. The method is characterized by that upon completion of the trench filling substrate 208 scraper 612 and squeegee 224 are retracted from the working zone in a synchronized movement (Block 1120) and further characterized in that in course of the retraction at least scraper 612 remains in full contact with substrate 208. In some examples, squeegee 224, scraper 612 and substrate 208 are retracted in a synchronized movement and further characterized in that in course of the retraction the spatial location of the scraper 612, squeegee 224 and substrate 208 does not change and they remains in full contact with substrate 208.

According to the method scraper 612 is following squeegee 224 to remove the excess filler from substrate 208 and accumulate the excess filler on surface 904 of scraper 612 facing the squeegee (1124).

Upon completion of scraper 612, squeegee 224 and substrate 208 retraction movement of the squeegee further movement of the squeegee is initiated to remove accumulated on surface 904 of scraper 612, facing the squeegee excess filler. In order to collect the excess filler from surface 904 of scraper 612 the squeegee elevates as shown by arrow 908 (Block 1128), translates towards the scraper as shown by arrow 912 (Block 1132), contacts surface 904 of scraper 612 (Block 1136) with the excess filler and descends as shown by arrow 924 (Block 1140) towards substrate 208 while collecting the excess filler accumulated along the surface of the scraper.

The filler could be provided different properties. For example, filler conductivity could be regulated by including in the formulation metal or carbon black particles. The material loading is limited by the viscosity of the solution to be used in printing. Resistivity in the range of can range from 10⁻¹⁴ to 10² ohms/square can be obtained by addition of different conductive particles.

Metal particles incorporated into the filler could be used in preparation of a ribbon to provide Magnetic Ink Character Recognition (MICR) for encoding information onto checks and other identifiable documents.

Transfer technique could be used to print on a wide variety of substrates, such as semiconductors, ceramics, paper, fabric, PET, polyimide, polypropylene, and other synthetic films expanding product design and manufacturing options.

Different thickness conductive and not conductive layers could be generated and included into the transfer mask.

Thermal transfer printing brings an inherent ability to provide uniform and consistent line widths and thicknesses. Resolution of the laser printheads used for laser assisted printing supports highest resolution and lowest feature existing in the industry.

In situ production of the transfer pattern with variable feature size could simplify and reduce manufacturing costs of such electronic items like RFID antennas, membrane keyboards, printed circuit boards, decorative items and other printed electronics and are all possible applications using thermal transfer printing technology.

While the apparatus and method have been particularly shown and described with reference to specific examples, it should be understood by those skilled in the art that various changes in form and detail may be made therein without departing from the spirit and scope of the as defined by the appended claims.

1. An apparatus for generating a transfer pattern by filling filler into a trench within a web substrate, comprising:
a support configured to fetch a segment of the of the web substrate with at least one trench into a working zone of the device;
a squeegee configured to fill the trench with a filler deposited on the web substrate by a filler delivery mechanism; and
wherein upon completion of the trench filling the substrate and the squeegee are translated from the working zone in a synchronized movement and wherein in course of the translation movement the squeegee remains in full contact with the substrate.

2. An apparatus for generating a transfer printing pattern by filling filler into a trench within a web substrate, comprising:
a support configured to fetch a segment of the of the web substrate with at least one trench into a working zone of the device;
a squeegee configured to fill the trench with a filler deposited on the web substrate by a filler delivery mechanism;
a scraper configured to follow the squeegee and remove from the web substrate excess filler occasionally deposited on area surrounding the trench; and
wherein upon completion of the trench filling at least the substrate and the scraper are retracted (translated) from the working zone in a synchronized movement and wherein in course of the retraction the scraper remains in full contact with the substrate.

3. The according to claim 2, wherein the scraper that follows the squeegee removes the excess filler from the substrate and accumulates the excess filler removed from the substrate on the substrate in front the scraper and on the surface of the scraper facing the squeegee.

4. The apparatus according to claim 2 further comprising retracting the squeegee concurrently to retracting the scraper and the substrate and maintaining in course of the retraction a constant spatial relation between the substrate, squeegee and the scraper.

5. The apparatus according to claim 2, wherein upon completion of the retraction the squeegee is further translated to contact the surface of the scraper facing the squeegee and collect the excess filler accumulated on the surface of the scraper facing the squeegee.

6. The apparatus according to claim 5, wherein in order to collect the excess filler from the surface of the scraper the squeegee elevates, translates towards the scraper, contacts the scraper surface with the excess filler and descends towards the substrate while collecting the excess filler accumulated along the surface of the scraper.

7. The apparatus according to claim 6, wherein the squeegee transfers and combines (recycles) the excess filler collected from the surface of the scraper with the filler deposited on the substrate by a filler delivery mechanism.

8. The apparatus according to claim 7, wherein in course of at least the trench by filler filling vacuum holds the substrate in a rigid and static form.

9. The apparatus according to claim 8, wherein vacuum releases the substrate in course of the substrate translation such as to facilitate the substrate over the support translation.

10. The apparatus according to claim 8, wherein over pressure is built through the vacuum as to facilitate the substrate over the support translation.

11. The apparatus according to claim 10, wherein the filler is a conductive paste.

12. A method for generating a transfer pattern comprising:
providing a substrate with at least one trench into a working zone and holding the substrate static;
employing a squeegee configured to fill the trench with a filler deposited on the substrate by a filler delivery mechanism;
employing a scraper configured to follow the squeegee and remove from the substrate excess filler occasionally deposited on area surrounding the trench; and
retracting upon completion of the trench filling at least the substrate and the scraper from the working zone in a synchronized movement and wherein in course of the retraction the scraper remains in full contact with the substrate.

13. The method according to claim 12 wherein also using the scraper is following the squeegee to remove the excess filler from the substrate and accumulating the excess filler on surface of the scraper facing the squeegee.

14. The method according to claim 12 further comprising retracting the squeegee concurrently to retracting the scraper and the substrate and maintaining in course of the retraction a constant spatial relation at least between the squeegee and the scraper.

15. The method according to claim 12, wherein upon completion of the retraction further translating the squeegee to contact the surface of the scraper facing the squeegee and collecting the excess filler accumulated on the surface of the scraper facing the squeegee.

16. The method according to claim 15, wherein in order to collect the excess filler from the surface of the scraper the squeegee elevates, translates towards the scraper, contacts surface of the scraper with the excess filler and descends towards the substrate while collecting the excess filler accumulated along the surface of the scraper.

17. The method according to claim 16, wherein also using vacuum to hold the substrate in a rigid and static form in course of at least the trench by filler filling.

18. The method according to claim 17 wherein also releasing the vacuum in course of the substrate translation such as to facilitate substrate over the support translation.

19. A system for transfer printing of a pattern comprising:
a delivery and translation unit configured to deliver into a working zone and translate from the working zone a substrate bearing a pattern including at least one trench;
a unit configured to fill-in the transfer pattern by a filler, said unit including:
a support configured to receive delivered into the working zone and hold the substrate with at least one trench in the working zone;
a squeegee configured to fill the trench with a filler deposited on the substrate by a filler delivery mechanism and a scraper configured to follow the squeegee and remove from the substrate excess filler occasionally deposited on area surrounding the trench; and
wherein upon completion of the trench filling and before the substrate is displaced to transfer the pattern to the receptor, at least the substrate and the scraper are retracted (translated) from the working zone in a synchronized movement and wherein in course of the retraction the scraper remains in full contact with the substrate.

20. The system according to claim 19 further comprising a unit for delivery of a receptor configured to receive the filler filling the trench (transfer pattern) and a mechanism for transfer of the filler from the trench to the receptor.

21. The system according to claim 19 further comprising a computer configured to control at least the substrate delivery and translation unit, the unit configured to fill-in the transfer pattern by the filler and the unit configured to deliver the receptor.

22. The system according to claim 20 wherein the unit configured to transfer the filler from the trench to the receptor is a thermal transfer unit activated by electromagnetic radiation.
